(19) United States
(12) Patent Application Publication
(10) Pub. No.: US 2008/0296636 A1
(43) Pub. Date: Dec. 4, 2008

(54) Devices and integrated circuits including lateral floating capacitively coupled structures

(76) Inventors: Mohamed N. Darwish, Campbell, CA (US); Richard A. Harris, Karana Downs (AU); Muhammed Ayman Shibib, Mountain View, CA (US); Andrew J. Morrish, Saratoga, CA (US); Robert Kuo-Chang Yang, San Jose, CA (US)

Correspondence Address: LUMEN PATENT FIRM, INC., 2345 YALE STREET, SECOND FLOOR, PALO ALTO, CA, 94306, US

(21) Appl. No.: 12/156,670

(22) Filed: Jun. 2, 2008

Related U.S. Application Data
(60) Provisional application No. 60/932,851, filed on May 31, 2007.

(51) Int. Cl. H01L 29/808; H01L 21/28; H01L 29/06

(52) U.S. Cl. 257/256; 257/488; 438/454; 257/E29.31; 257/E29.01; 257/E21.158

(57) ABSTRACT

According to the present invention, semiconductor device breakdown voltage can be increased by embedding field shaping regions within a drift region of the semiconductor device. A controllable current path extends between two device terminals on the top surface of a planar substrate, and the controllable current path includes the drift region. Each field shaping region includes two or more electrically conductive regions that are electrically insulated from each other, and which are capacitively coupled to each other to form a voltage divider dividing a potential between the first and second terminals. One or more of the electrically conductive regions are isolated from any external electrical contact. Such field shaping regions can provide enhanced electric field uniformity in current-carrying parts of the drift region, thereby increasing device breakdown voltage. Further aspects of the invention relate to device integration, efficient fabrication of field shaping regions and device isolation features using the same mask for both, and improved device structures.

### CROSS REFERENCE TO RELATED APPLICATIONS

This application claims the benefit of U.S. provisional patent application 60/932,851, filed on May 31, 2007, entitled “A Monolithically Integrated TBU Using Lateral Floating Capacitively Coupled Transistors”, and hereby incorporated by reference in its entirety.

### FIELD OF THE INVENTION

This invention relates to high voltage semiconductor devices.

### BACKGROUND

The breakdown voltage of a semiconductor device is significantly affected by the electric field distribution within and near the device. Accordingly, methods of increasing device breakdown voltage by altering or controlling the electric field distribution have been extensively developed in the art, and are often referred to as field shaping methods. Structures employed for field shaping include guard rings, floating field plates, and biased charge control electrodes.

For example, in U.S. Pat. No. 6,190,948, field shaping between an active region of a device and a floating field ring around the device is provided by several overlapping floating field plates between the active region and the field ring. The overlap of the field plates increases the capacitive coupling between the plates. In this example, field shaping is provided in a termination region of the device.

Field shaping has also been employed within devices (e.g., between the source and drain of a field effect transistor (FET)) to increase breakdown voltage. For example, in U.S. Pat. No. 6,717,230, biased charge control electrodes in a drift region of a FET are employed to provide field shaping within the drift region. In U.S. Pat. No. 6,110,804, floating field conductors are disposed above the top surface of a FET drift region to provide field shaping at the surface of the drift region. Charge is injected onto the floating field conductors (e.g., by biasing the device into breakdown) such that a depletion region is formed in the drift region.

However, these examples of known field shaping approaches also provide examples of undesirable complications that can arise in practice. For example, fabrication of overlapping field plates as in U.S. Pat. No. 6,190,948 can be relatively complicated. Individual biasing of charge control electrodes as in U.S. Pat. No. 6,717,230 can be complicated to implement in practice. In U.S. Pat. No. 6,110,804, the injection of charge onto the floating field conductors can generate practical issues, such as providing the proper amount of injected charge, and dealing with leakage of the injected charge over time.

Accordingly, it would be an advance in the art to provide field shaping having improved performance with structures that can be provided by relatively simple fabrication methods.

### SUMMARY

According to the present invention, semiconductor device breakdown voltage can be increased by embedding field shaping regions within a drift region of the semiconductor device. A controllable current path extends between two device terminals on the top surface of a planar substrate, and the controllable current path includes the drift region. Each field shaping region includes two or more electrically conductive regions that are electrically insulated from each other, and which are capacitively coupled to each other to form a voltage divider dividing a potential between the first and second terminals. One or more of the electrically conductive regions are isolated from any external electrical contact. Such field shaping regions can provide enhanced electric field uniformity in current-carrying parts of the drift region, thereby increasing device breakdown voltage.

Some aspects of the present invention can be better appreciated by comparison to an invention of Yang et al. (US 2006/0255401). In US 2006/0255401, a series capacitive structure is vertically disposed in a trench adjacent to a drift region having a vertical controllable current path to increase breakdown voltage. Such a vertical structure tends to require several deposition and etching steps for device fabrication, which can make the fabrication process complicated and difficult to control. Difficulty in controlling process parameters can reduce performance. For example, poorly controlled conductor and dielectric layer thicknesses in the vertical trench can result in RC time delays that degrade device switching performance.

In contrast, the present invention provides a lateral geometry for the field shaping regions. This lateral geometry advantageously simplifies processing, as can be seen in the exemplary fabrication sequences of FIGS. 4a-6c.

Further significant aspects of the invention relate to device integration, efficient fabrication of field shaping regions and device isolation features using the same mask for both, and improved device structures for application to integrated transient blocking units or to other monolithically integrated circuits using lateral floating capacitively coupled (LFCC) structures for other applications. Efficient integration according to principles of the invention can yield a simple manufacturing process for an integrated circuit that fully utilizes the LFCC features and functions to give a more efficient and smaller area integrated circuit, thus reducing cost.

### BRIEF DESCRIPTION OF THE DRAWINGS

FIG. 1a shows a top view of a device according to an embodiment of the invention.

FIG. 1b shows a cross section view through a field shaping region of the device of FIG. 1a.

FIG. 1c shows a cross section view through an active region of the device of FIG. 1a.

FIG. 2 shows a top view of a device according to another embodiment of the invention.

FIG. 3 shows a top view of a device according to a further embodiment of the invention.

FIGS. 4a-f show a first exemplary device fabrication sequence suitable for fabricating embodiments of the invention.

FIGS. 5a-e show a second exemplary device fabrication sequence suitable for fabricating embodiments of the invention.

FIGS. 6a-c show a third exemplary device fabrication sequence suitable for fabricating embodiments of the invention.

FIG. 7 shows a cross section view through an active region of a device according to an alternate embodiment of the invention.

FIGS. 8a-c show an example of integration with lateral device isolation according to an embodiment of the invention.

FIG. 9 shows an example of vertical isolation according to an embodiment of the invention.

FIGS. 10a-b show an example of an improved JFET according to an embodiment of the invention.

### DETAILED DESCRIPTION

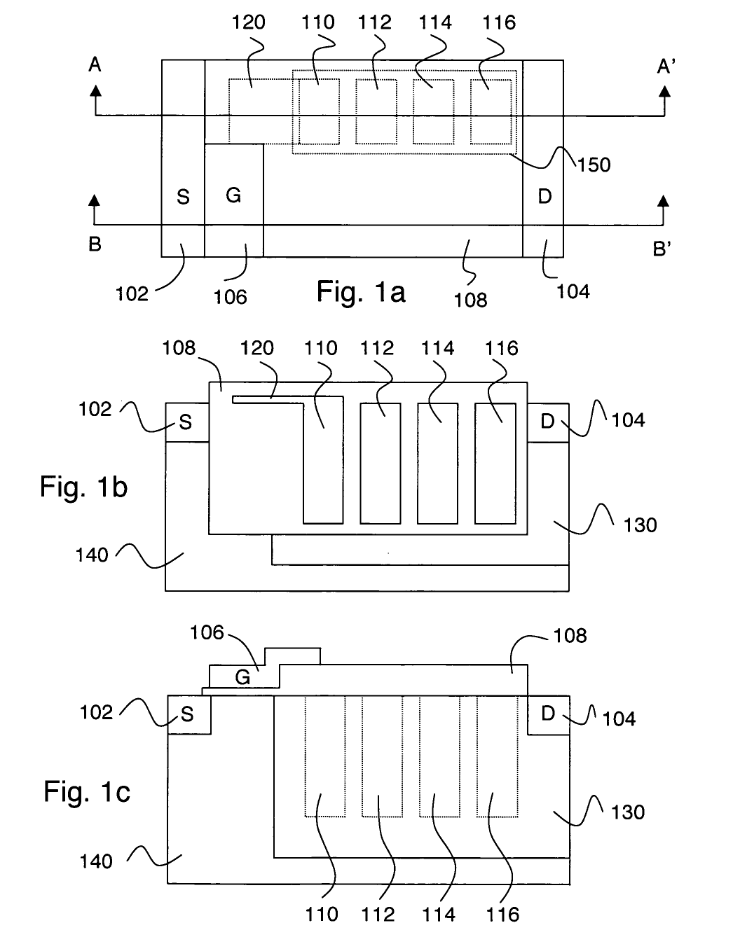

FIG. 1a shows a top view of a device according to an embodiment of the invention. In this example, current flow between a source 102 and a drain 104 is controlled by a gate 106. Thus the device of this example is a field effect transistor (FET). FIG. 1b shows a cross section view through a field shaping region of the device of FIG. 1a along line AA′. FIG. 1c shows a cross section view through an active region of the device of FIG. 1a along line BB′. To understand the operation of this example, it is helpful to regard the active region (BB′, FIG. 1c) as the main part of the device, since this region provides the basic transistor switching functionality.

In the view of FIG. 1c (active region) source 102 and drain 104 are disposed at a top surface of a planar substrate 140, which in this example is p-type silicon. Drain 104 is surrounded by an n-well 130, also of silicon. An insulator 108 (SiOx in this example) is disposed on top of n-well 130 and p-substrate 140. Gate 106 is separated from source 102, n-well 130 and p-substrate 140 by a thin layer of oxide 108. As is well known in the FET art, appropriate biasing of gate 106 can provide or remove a conductive channel extending from source 102 to n-well 130 along the surface of p-substrate 140 under gate 106. Current flow within n-well 130 from the channel to drain 108 is primarily driven by electric fields (as opposed to diffusion), so n-well 130 is referred to as a “drift region”.

According to principles of the invention, the electric field distribution in the drift region can be made more uniform by embedding one or more field shaping regions in the drift region. Such increased field uniformity can advantageously increase breakdown voltage. In the example of FIGS. 1a-c, FIG. 1b shows a cross section view through a field shaping region, along line AA′ of FIG. 1a. Several electrically conductive regions 110, 112, 114, and 116 (made of polysilicon in this example) are separated from each other and surrounded by oxide 108. For brevity, these electrically conductive regions will be referred to as “plates” in the following description, but practice of the invention does not depend critically on the shape of the electrically conductive regions.

The separation between plates 110, 112, 114, and 116 is selected to provide capacitive coupling between the plates. In this example, plates 112, 114, and 116 are floating (i.e., isolated from any external electrical contact), and plate 110 is connected to gate 106 via a connection 120. More generally, field shaping regions according to embodiments of the invention include two or more conducting plates capacitively coupled to each other within an insulating matrix. At least one of these plates is floating. The floating plates preferably have substantially no net charge. It is possible for all plates to be floating, but it is usually preferred for one of the plates to be connected to the gate, with the remaining plates being floating, as in this example. If the gate is connected to one of the plates, it is preferably connected to the nearest plate in the field shaping region, also as shown in this example.

In addition to being capacitively coupled to each other, the plates are also capacitively coupled to the drift region (i.e., to n-well 130). The most significant effect of this capacitive coupling of the plates to the drift region is on the electric field distribution within the drift region of the active region of the device (e.g., n-well 130 in the view of FIG. 1c). Thus the field shaping region acts “laterally” in the sense that the plates along line AA′ affect the field distribution along line BB′. Lateral capacitive coupling of plates 110, 112, 114, and 116 to n-well 130 is provided by disposing the plates in an oxide-filled trench 150, as shown on FIG. 1a.

As indicated above, the capacitive coupling of the plates to each other, and the capacitive coupling of the plates to the drift region, allow electric field non-uniformity to be reduced in the drift region, thereby increasing breakdown voltage. Compositions, dimensions and/or properties of the field shaping regions can be predetermined to provide such increased field uniformity.

Relevant parameters include, but are not limited to: spacings between the plates, composition of the drift region, doping of the drift region, compositions of the plates, dopings of the plates, spacings between the plates and the drift region, compositions of the electrically insulating regions of the field shaping regions, and dielectric constants of the electrically insulating regions of the field shaping regions. Detailed design of appropriate field shaping regions for practicing the invention in connection with any specific device design is within the skill of an ordinary art worker, in view of the principles described herein.

An advantageous feature of the present invention is that critical dimensions, such as plate to plate spacing, and plate to drift region spacing, are lateral dimensions that can be defined lithographically. This advantage is especially pronounced in comparison with the vertical structure of US 2006/0255401, where the plate to plate spacing is a vertical dimension.

Another advantageous feature of the present invention is that embedding the plates in the drift region allows improved plate to plate capacitive coupling and plate to drift region capacitive coupling compared to arrangements where floating plates or rings are disposed on a top surface of a device. Such conventional “surface effect” field shaping arrangements tend to suffer from poor coupling of the floating plates to each other and to the active part of the device. In contrast, plates in embodiments of the invention can have substantially larger capacitive coupling to each other due to their “face to face” geometry, as opposed to the “edge to edge” geometry of a conventional surface effect field shaping arrangement.

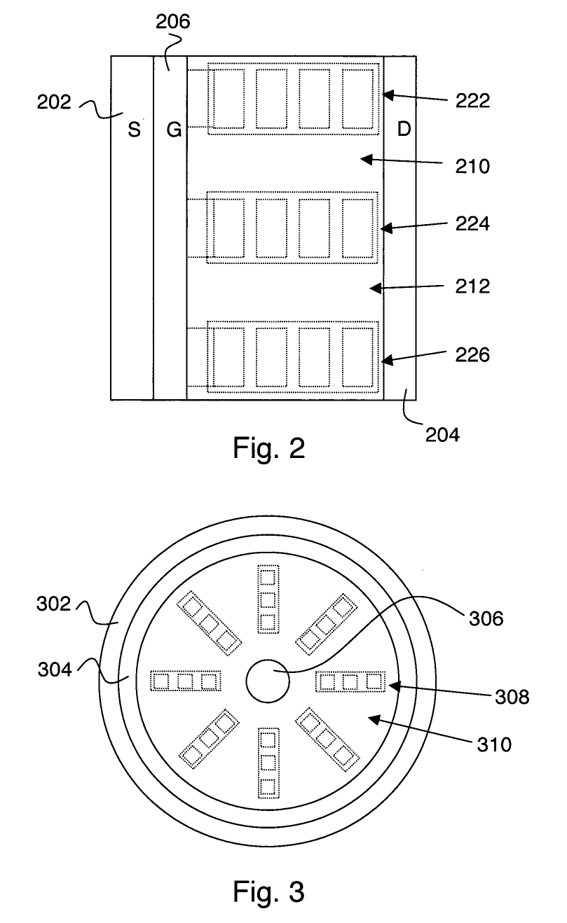

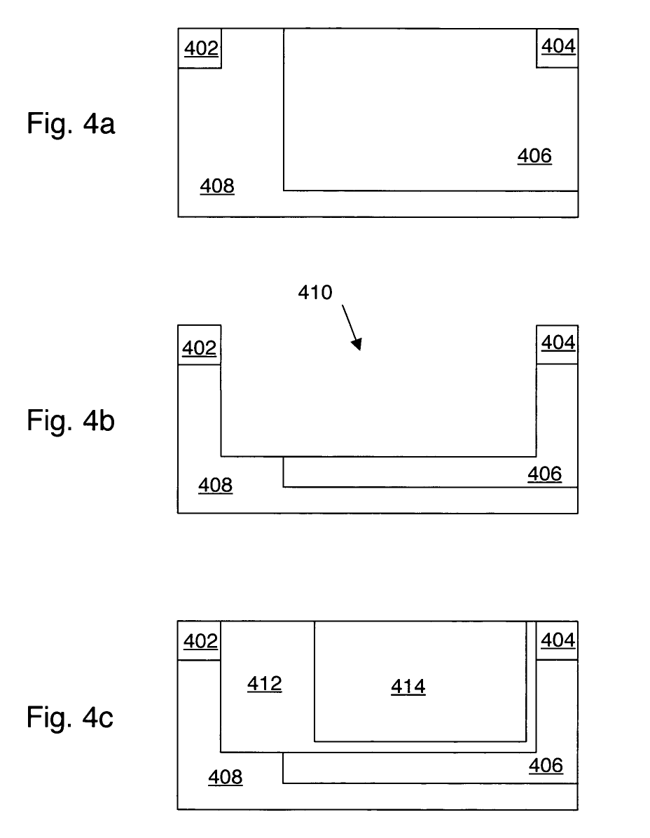

As indicated above, it is often helpful to regard devices according to embodiments of the invention as having active regions, where most or all of the current flows, and field shaping regions which serve to control the field distribution in the active regions. The invention can be practiced with various geometrical arrangements of active regions and field shaping regions. For example, FIG. 2 shows a top view of a device having alternating field shaping regions 222, 224, and 226 disposed between active regions 210 and 212. These active and field shaping regions are all part of a drift region between a drain 204 and a gate 206 of a FET having a source 202. As another example, FIG. 3 shows a top view of a device having a drain 306 surrounded by a gate 304 and a source 302, where field shaping regions such as 308 and active regions such as 310 are radially arranged around drain 306.

Fabrication of embodiments of the invention can be regarded as adding fabrication of the field shaping regions to an otherwise conventional process flow. Accordingly, the following exemplary fabrication sequences show process steps for a field shaping region in cross section (e.g., AA′ on FIG. 1a).

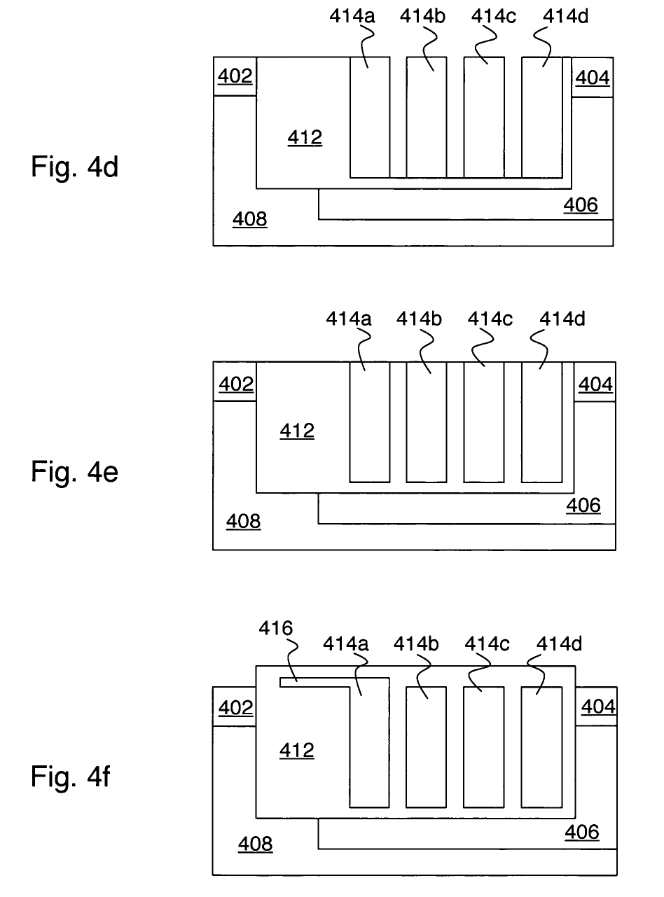

FIGS. 4a-f show a first exemplary device fabrication sequence suitable for fabricating embodiments of the invention. FIG. 4a shows a source 402, a drain 404, an n-well 406 and a p-substrate 408 formed in a semiconductor material. Methods for fabricating such a structure are well known, and need not be described here. FIG. 4b shows the result of etching a trench 410 in the structure of FIG. 4a. Trench 410 is filled sequentially in two steps. The first step is to partially fill trench 410 with oxide 412, and the second step is to fill the remainder of trench 410 with polysilicon 414. FIG. 4c shows the result of these two steps. Oxide 412 can be formed by oxidation of the trench wall material and/or by deposition of oxide. Oxide 412 covers all surfaces of trench 410 (i.e., the bottom surface and all four side surfaces), such that there is no direct physical contact between polysilicon 414 and any surface of trench 410.

FIG. 4d shows the result of etching polysilicon 414 into several plates, labeled as 414a, 414b, 414c, and 414d. FIG. 4e shows the result of filling in the gaps between the plates with oxide. FIG. 4f shows the result of depositing oxide to cover the top surfaces of the plates, and of providing a polysilicon gate connector 416 connected to plate 414a. Connection of one of the plates to the gate with connector 416 (also shown as 120 on FIG. 1a) can be accomplished with conventional processing methods. The cross section of FIG. 4f is essentially the same as the cross section of FIG. 1b, thereby establishing the sequence of FIGS. 4a-f as one approach for fabricating embodiments of the invention.

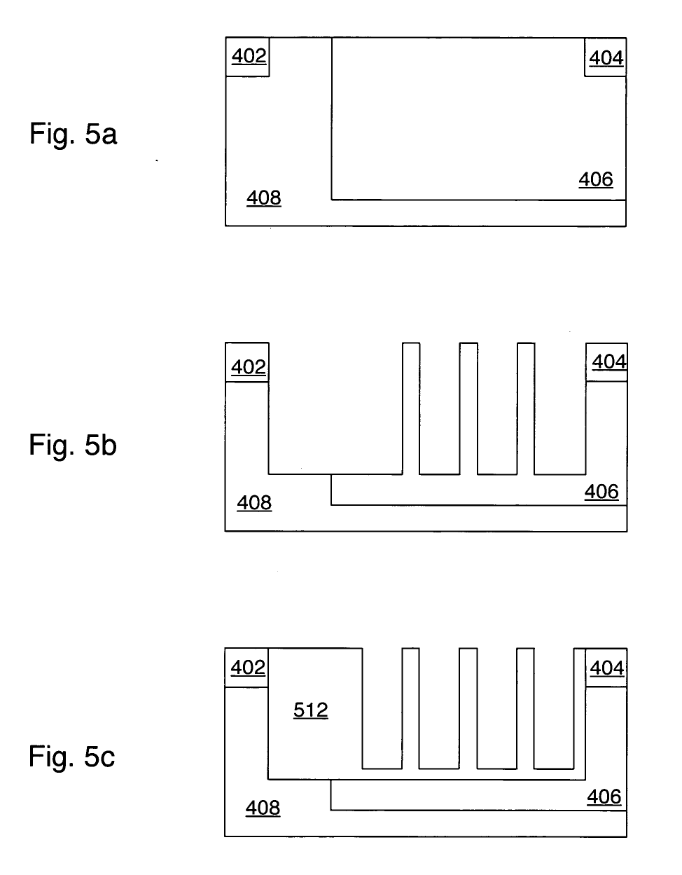

FIGS. 5a-e show an alternate fabrication approach, where oxidation of silicon islands is employed to define the plate to plate separation. FIG. 5a shows the same stating point as FIG. 4a. FIG. 5b shows the result of etching the structure of FIG. 5a to form a trench having semiconductor islands in it. FIG. 5c shows the result of oxidizing the structure of FIG. 5b such that the semiconductor islands are oxidized and become part of oxide 512. Deposition of oxide may also be employed at this step (e.g., to deposit thicker layers of oxide than can readily be obtained by oxidation). FIG. 5d shows the result of depositing polysilicon in the recesses of oxide 512, thereby forming polysilicon plates 514a, 514b, 514c, and 514d. FIG. 5e shows the result of depositing oxide to cover the top surfaces of the plates, and of providing a polysilicon gate connector 516 connected to plate 514a. Here also, the structure of FIG. 5e is essentially that of FIG. 1b.

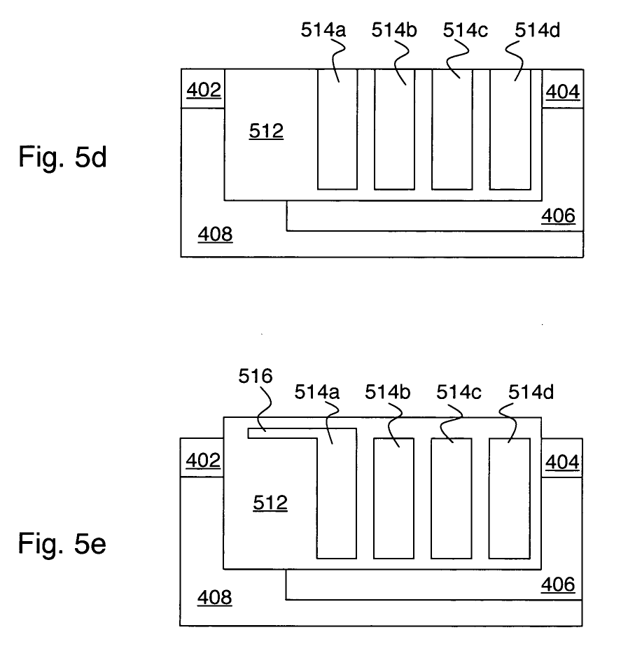

FIGS. 6a-c show another alternate fabrication approach. The approach of FIGS. 6a-c is preferred, since it can provide improved control of plate to plate spacing. FIG. 6a shows a similar structure as in FIG. 4d, where polysilicon plates 414a, 414b, 414c, and 414d have been formed by etching a single polysilicon region. FIG. 6b shows the result of oxidizing the structure of FIG. 6a such that the gaps between the polysilicon plates are not completely filled in. FIG. 6c shows the result of filling the remaining gaps with polysilicon plates 614a, 614b, and 614c, covering the top surfaces of the plates with oxide and providing gate connector 416.

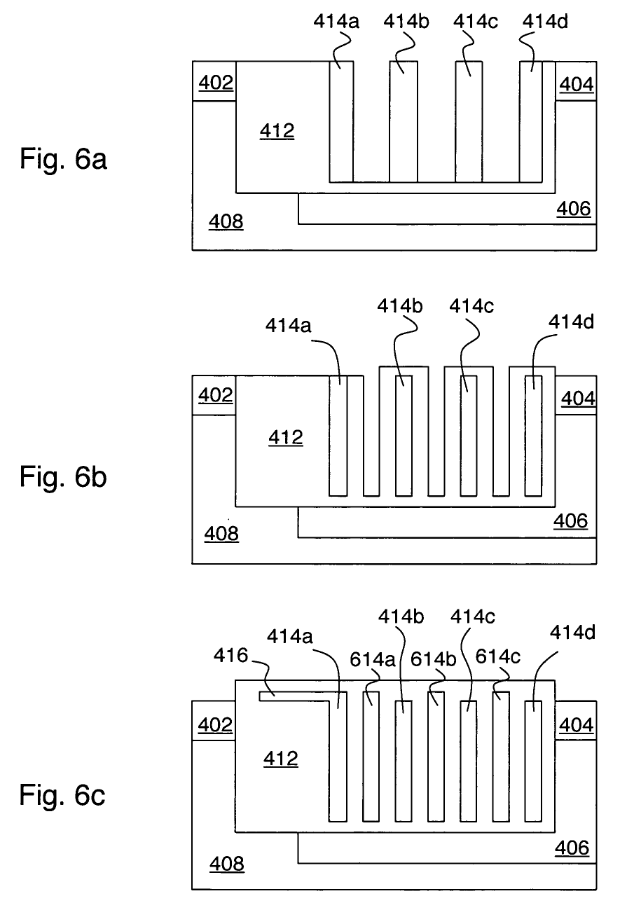

One of the main advantages of the invention is that field shaping region fabrication methods suitable for practicing the invention tend to be broadly compatible with fabrication of a wide variety of active region device structures. For example, FIG. 7 shows an active region cross section similar to the cross section of FIG. 1c, except that a p-region 710 is added to provide dual conduction. The field distribution within the active region of the example of FIG. 7 can be made more uniform according to the principles of the invention as described above. Furthermore, the presence of p-region 710 in the active region will have no significant effect on fabrication of the field shaping regions.

Consideration of these fabrication methods highlights further advantages of the invention, especially as compared to approaches having vertically stacked plates. In particular, all of the plates of the field shaping regions of embodiments of the invention can be formed in one or two depositions, while vertical approaches can require one deposition step per plate. All of the insulating spacers between plates in embodiments of the invention can also be formed in a single oxidation step, while vertical approaches can require one deposition step per insulating spacer. As a result of these fabrication advantages, embodiments of the invention can readily be designed to provide enhanced field shaping by increasing the number of floating plates.

The surface accessibility of the polysilicon plates can enable further processing for enhanced performance. For example, polycides can be employed to reduce polysilicon resistivity, and multiple resurf can be employed to enhance performance. The lateral geometry of embodiments of the invention facilitates integration, e.g., adding functionality to power integrated circuits (PICs). Such PICs can be employed in various applications, such as switching mode power supplies.

The preceding description has been by way of example as opposed to limitation, and the invention can also be practiced according to many variations of the given examples. For example, the roles of p-type and n-type material can be exchanged in the examples and in any embodiment of the invention. The invention is applicable to any semiconductor device having a controllable current path, including but not limited to: transistors, bipolar transistors, field effect transistors, thyristors, insulated-gate field effect transistors, junction field effect transistors, and MOSFETs. The invention is applicable to any material system suitable for fabricating semiconductor devices, including but not limited to: silicon, group III-V compound semiconductors, group II-VI compound semiconductors, group IV elemental semiconductors, and group IV-IV compound semiconductors.

The preceding description has focused on the use of lateral floating capacitively coupled (LFCC) structures for field shaping to improve high voltage device performance. There are other aspects of LFCC structures that can also be advantageous in practice. More specifically, LFCC structures can be employed as device isolation structures, fabrication of LFCC structures can be efficiently combined with fabrication of device isolation features, and LFCC structures can be used to provide improved device performance. The following description will provide examples of these three aspects of embodiments of the invention.

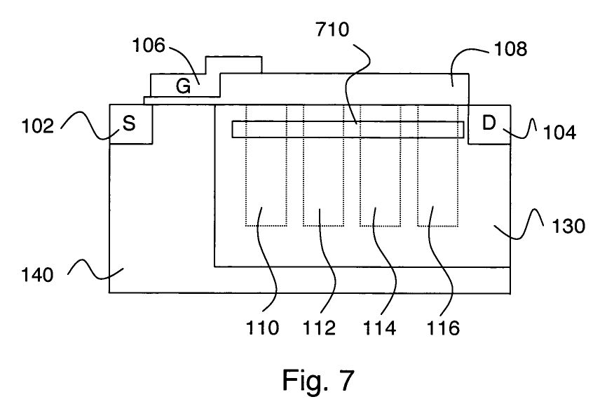

FIGS. 8a-c show an example of device integration and isolation according to an embodiment of the invention. FIG. 8a shows a schematic diagram of a transient blocking unit (TBU). A TBU is a circuit which normally has a low series resistance, but which rapidly and automatically switches to a high resistance current blocking state in response to an over-voltage or over-current condition. A TBU is thereby capable of providing protection for a series-connected load. In TBU applications where high voltages must be handled, a core TBU configuration as shown in the schematic of FIG. 8a can be employed. In this example, transistors Q3, Q4, and Q5 are low/medium voltage transistors arranged in the usual bi-directional TBU configuration. The core TBU formed by transistors Q3, Q4, and Q5 controls the switching of high voltage depletion mode transistors Q1 and Q2. Here transistors Q1 and Q2 provide the voltage handling capability of the overall TBU circuit.

FIG. 8b shows an example of how the schematic of FIG. 8a can be realized as an integrated circuit. In this example, transistors Q1 and Q2 include LFCC field shaping regions as described above (e.g., in connection with FIG. 2) to improve their device performance. Also shown on FIG. 8b are various device isolation features. More specifically, outer isolation trenches 802 and 806 each include multiple floating conductive plates (one plate in trench 802 is referenced as 804, and one plate in trench 806 is referenced as 808) which are capacitively coupled to each other. Having a single plate, as in the case of trench 814 and plate 816, spreads the equipotential across its whole length (perpendicular to line 830 in FIG. 8b) whereas the different plates in trench 802 can sustain a uniform potential gradient in the smallest possible distance and that would help in, for example, reducing the size of the termination region of high voltage transistor Q2 and provide electrical isolation simultaneously. Similarly, the two conductive plates 824 and 826 in insulating trench 822 serve to divide the voltage between Q1 and Q3.

Isolation trench 818 between Q3 and Q5 includes a conductive plate 820. Similarly, isolation trench 814 includes conductive plate 816 and isolation trench 810 includes conductive plate 812. FIG. 8c shows a cross section view of the example of FIG. 8b taken along line 830. For all of these isolation features, material in the trench and surrounding the conductive plate or plates is electrically insulating.

Fabrication of these isolation features can be accomplished as described above in connection with LFCC field shaping region fabrication. For example, the conductive regions can be made from poly-silicon, and the insulating regions can be made of oxide. In fact, it is preferred to form the isolation features with the same processing steps that are used to define the LFCC structures within Q1 and Q2. The same mask pattern(s) can be used to define LFCC field shaping regions and device isolation regions, whether or not the device isolation regions include floating conductive plates. In this manner, fabrication efficiency can be increased, thereby reducing cost.

Device isolation features can be disposed between active devices of the integrated circuit (e.g., trenches 810, 814, 818, and 822). Device isolation features can also be disposed between an active device and a peripheral region of the integrated circuit (e.g., trenches 802 and 806). These two examples can be regarded as relating to lateral isolation.

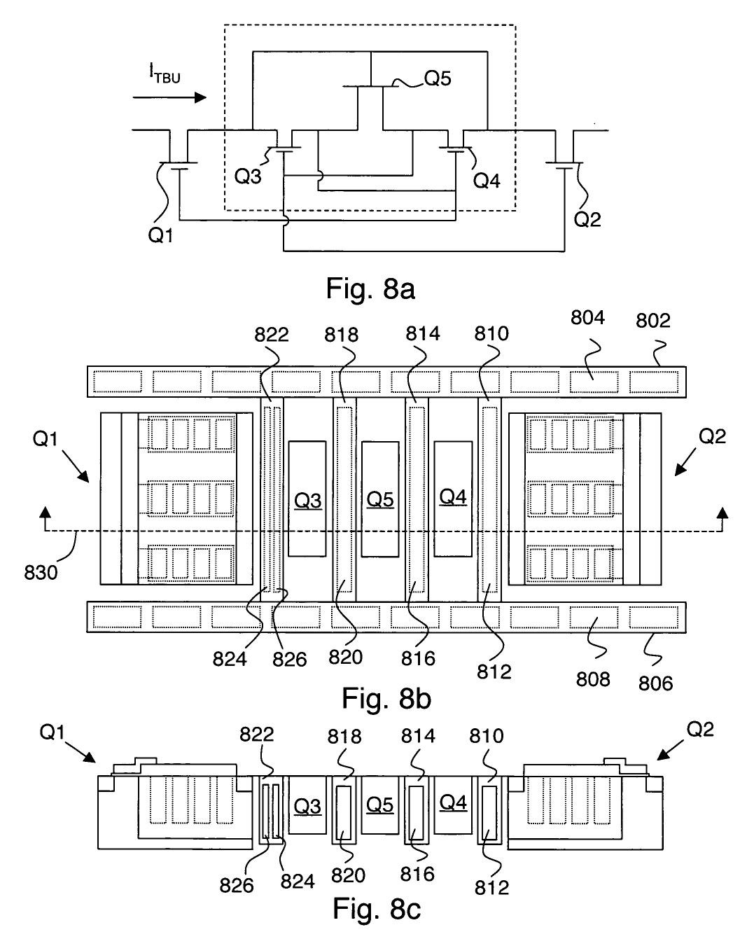

Vertical isolation can also be provided by embodiments of the invention. For example, FIG. 9 shows an example of a high voltage semiconductor resistor having vertical isolation. More specifically, a resistor 906 having terminals 902 and 904 is disposed on an insulator 908 on top of an LFCC structure 912 having conductive plates 914 which is on top of a conductive substrate 910. Capacitively coupled conductive plates 914 can be disposed under insulator 908 to improve isolation between the resistor and substrate 910. Adding such an LFCC isolation region can substantially increase the voltage handling capability of the device (by about a factor of two, if other aspects of the device geometry are the same). Fabrication of such an LFCC vertical isolation structure can be accomplished as described above.

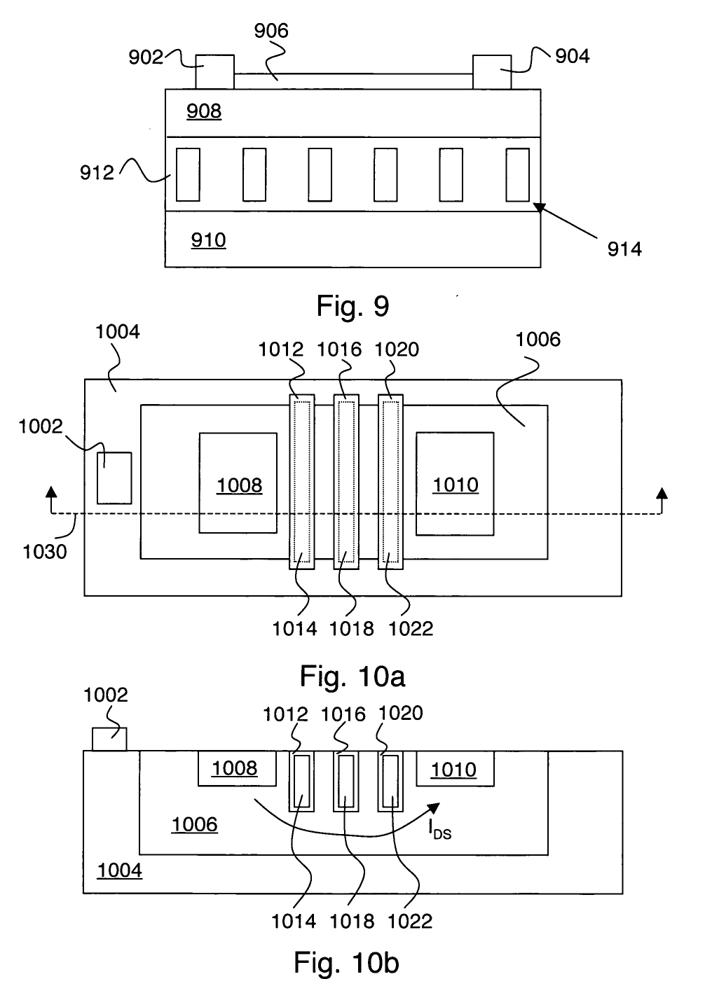

FIGS. 10a-b show an example where an LFCC structure is included in an active device to improve its performance. FIG. 10a is a top view and FIG. 10b is a side view of a junction field effect transistor having an inverted gate configuration. Here terminals 1008 and 1010 are the source and drain, and are disposed at the top surface of the planar substrate and are embedded in body region 1006. Body region 1006 and terminals 1008 and 1010 have the same doping type (i.e., n-type or p-type). A gate region 1004 is disposed below body region 1006 and has the opposite doping type relative to body region 1006. Optionally, a top gate terminal 1002 can provide surface electrical access to gate region 1004. A controllable current path I_{DS} extends between terminals 1008 and 1010 in body region 1006.

Note that in this approach, the distance between terminals 1008 and 1010 can be significantly reduced compared to a conventional JFET having the same voltage rating, where a gate diffusion would exist in between terminals 1008 and 1010. This aspect of the embodiment of FIGS. 10a-b is particularly useful for higher voltage JFETs where, in conventional JFETs, the drain to gate separation limits the breakdown voltage rating of the device. Another significant advantage, besides the smaller area, is that the new structure is relatively insensitive to misalignment of gate and drain, thereby improving yield and reducing manufacturing cost.

This device also includes a current path shaping region having electrically conductive regions 1014, 1018 and 1022 capacitively coupled to each other (by proximity) and electrically insulated from each other (by insulating trenches 1012, 1016, and 1020 respectively). The controllable current path IDS is between the current path shaping region and gate region 1004. Fabrication of such current path shaping regions can be accomplished as described above.

1. An integrated circuit comprising:
a) at least one high voltage semiconductor device comprising:
a first terminal and a second terminal both disposed at a top surface of a planar substrate, wherein a controllable current path extends between said first and second terminals and wherein said controllable current path includes a drift region between said first and second terminals;
one or more field shaping regions disposed between said first and second terminals and embedded in said drift region;
wherein each of said field shaping regions comprises an electrically insulating region within which a plurality of electrically conductive regions are electrically insulated from each other, and which are capacitively coupled to each other to form a voltage divider dividing an electric potential between said first and second terminals, wherein one or more of said electrically conductive regions in each said field shaping region are isolated from any external electrical contact;
b) one or more isolation features disposed between said at least one high voltage device and another part of said integrated circuit;
wherein each of said one or more isolation features comprises an electrically insulating region within which one or more electrically conductive regions are electrically isolated from each other and capacitively coupled to each other.

2. The integrated circuit of claim 1, wherein said another part of said integrated circuit comprises another active device of said integrated circuit.

3. The integrated circuit of claim 1, wherein said another part of said integrated circuit comprises a peripheral region of said integrated circuit.

4. The integrated circuit of claim 1, wherein said another part of said integrated circuit comprises a substrate of said integrated circuit.

5. The integrated circuit of claim 1, wherein at least one of said one or more isolation features comprises an electrically insulating region within which two or more electrically conductive regions are electrically isolated from each other and capacitively coupled to each other.

6. A method of fabricating a high voltage integrated circuit, the method comprising:
etching one or more trenches in a drift region of a semiconductor device having first and second terminals disposed at a top surface of a planar substrate, wherein a controllable current path extends between said first and second terminals, and wherein said controllable current path includes said drift region;
filling each said trench with a field shaping region, wherein each field shaping region comprises a plurality of electrically conductive regions which are electrically insulated from each other, and which are capacitively coupled to each other to form a voltage divider dividing an electric potential between said first and second terminals, wherein one or more of said electrically conductive regions in each said field shaping region are isolated from any external electrical contact;
etching one or more isolation features separating said semiconductor device from another part of said integrated circuit;
wherein said etching one or more trenches in said drift region and said etching one or more isolation features are performed by lithographic processing according to a mask pattern that defines both said isolation features and said one or more trenches in said drift region.

7. A junction field effect transistor comprising:
a first terminal and a second terminal both disposed at a top surface of a planar substrate and both embedded in a body region having the same doping type as said first and second terminals, wherein a controllable current path extends between said first and second terminals in said body region;
one or more current path shaping regions disposed between said first and second terminals and embedded in said body region;
wherein each of said current path shaping regions comprises a plurality of electrically conductive regions which are electrically insulated from each other, and which are capacitively coupled to each other, wherein one or more of said electrically conductive regions are isolated from any external electrical contact;
a gate region disposed below said body region and having opposite doping type relative to said body region, wherein said controllable current path is between said gate region and said current path shaping regions.
